(19) United States
(12) Patent Application Publication
(10) Pub. No.: US 2026/0322384 A1
(43) Pub. Date: Oct. 15, 2026

(54) NEGATIVE VOLTAGE LEVEL SHIFTER WITH OUTPUT-CONTROLLED INTERMEDIATE NODE PULL-DOWN TRANSISTORS

(71) Applicant: GlobalFoundries U.S. Inc., Malta, NY (US)

(72) Inventors: Suresh Pasupula, Anantapur District (IN); Siva Kumar Chinthu, Bangalore (IN); Swanand Ramesh Pachghare, Mumbai (IN)

(21) Appl. No.: 19/176,431

(22) Filed: Apr. 11, 2025

(51) Int. Cl. H03K 19/0185

(52) U.S. Cl. CPC H03K 19/018521

(57) ABSTRACT

Disclosed is a negative voltage level shifter structure including: a positive supply voltage node at a positive voltage level (+V), a negative supply voltage node at a negative voltage level (−V), and a ground node at 0.0 volts (V). The structure includes two symmetric branches, each branch includes: a stack of two pull-up transistors and two pull-down transistors series-connected between the positive supply voltage node and negative supply voltage node; an output node between the two pull-up transistors and the two pull-down transistors; and an input node connected to a control terminal of a top pull-up transistor in the stack. Each branch also includes an additional pull-down transistor, which is connected between the ground node and an intermediate node between the two pull-down transistors in the stack and which has a control terminal connected to the output node.

### BACKGROUND

The present disclosure relates to on-chip voltage level shifters and, more particularly, to embodiments of a negative voltage level shifter.

Considerations in modern integrated circuit (IC) design include, but are not limited to, performance improvement, size scaling, and power consumption. Oftentimes design changes to improve one aspect of the design can yield an undesirable trade-off with respect to one or more of the other aspects of the design. For example, a negative voltage level shifter may be configured to translate (i.e., shift) an input signal (IN) that swings between 0.0 volts (V) and a positive voltage level (+V) to an output signal (OUT) that swings between +V and a negative voltage level (−V) (e.g., the absolute values of the negative and positive voltage levels are the same). To reduce power consumption, negative voltage level shifters have been developed that include low-voltage transistors (e.g., transistors rated for 1.8V-operation, for 1.5V-operation, or for 0.8V-operation). However, within such negative voltage level shifters, some of the low-voltage transistors operate outside their safe operating area (SOA) specifications.

### SUMMARY

Disclosed herein are embodiments of a positive voltage level shifter structure (hereinafter referred to as the structure). Generally, the structure can include: a negative supply voltage node, which is connected to receive a negative supply voltage at a negative voltage level, and a ground node at 0.0 volts (V). The structure can further include two symmetric branches. Each branch can include multiple pull-down transistors. The pull-down transistors can include: a first pull-down transistor, which is connected between an output node and an intermediate node; a second pull-down transistor, which is connected between the intermediate node and the negative supply voltage node; and a third pull-up transistor, which is connected between the ground node and the intermediate node and which has a control terminal connected to the output node.

In some embodiments of the structure, the pull-down transistors can be N-type field effect transistors (NFETs). That is, the structure can include: a negative supply voltage node, which is connected to receive a negative supply voltage at a negative voltage level, and a ground node at 0.0V. The structure can further include two symmetric branches. Each branch can include multiple pull-down transistors and, particularly, multiple NFETs. These NFETs can include: a first NFET, which is connected between an output node and an intermediate node; a second NFET, which is connected between the intermediate node and the negative supply voltage node; and a third NFET, which is connected between the ground node and the intermediate node and which has a gate connected to the output node.

In some embodiments of the structure, each of the symmetric branches can include multiple pull-up transistors (e.g., multiple PFETs) and multiple-pull-down transistors (e.g., multiple N-type field effect transistors (NFETs)). That is, the structure can include: a positive supply voltage node, which is connected to receive a positive supply voltage at a positive voltage level; a negative supply voltage node, which is connected to receive a negative supply voltage at a negative voltage level; and a ground node at 0.0 volts (V). The structure can further include two symmetric branches including a first branch and a second branch. The first and second branches can each include multiple pull-up transistors (e.g., PFETs) and multiple pull-down transistors (e.g., NFETs). Specifically, each branch can include a first pull-up transistor, a second pull-up transistor, a first pull-down transistor, and a second pull-down transistor connected in series between the positive supply voltage node and the negative supply voltage node. Each branch can further include a third pull-down transistor, which is connected between the ground node and an intermediate node located between the first pull-down transistor and the second pull-down transistor. The third pull-down transistor can have a control terminal, which is connected to an output node located between the second pull-up transistor and the first pull-down transistor. Each branch can further include a fourth pull-down transistor, which is connected between the ground node and an additional intermediate node located between the first pull-up transistor and the second pull-up transistor. The first pull-up transistor and the fourth pull-down transistor have control terminals connected to an input node. Additionally, within this structure, the second pull-down transistor in the first branch and the second pull-down transistor in the second branch are cross coupled. Furthermore, the second pull-up transistor in the first branch, the second pull-up transistor in the second branch, the first pull-down in the first branch, and the first pull-down transistor in the second branch have control terminals connected to the ground node.

It should be noted that all aspects, examples, and features of disclosed embodiments mentioned in the summary above can be combined in any technically viable way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic diagram illustrating an embodiment of a negative voltage level shifter;

FIG. 2 is a timing diagram illustrating input voltage pulses to and output voltage pulses from the structure of FIG. 1; and

FIGS. 3A-3B are timing diagrams illustrating some of the voltage pulses of FIG. 2 during power-up and power-down of the negative voltage level shifter of FIG. 1.

### DETAILED DESCRIPTION

As mentioned above, considerations in modern integrated circuit (IC) design include, but are not limited to, performance improvement, size scaling, and power consumption. Oftentimes design changes to improve one aspect of the design can yield an undesirable trade-off with respect to one or more of the other aspects of the design. For example, a negative voltage level shifter may be configured to translate (i.e., shift) an input signal (IN) that swings between 0.0 volts (V) and a positive voltage level (+V) to an output signal (OUT) that swings between +V and a negative voltage level (−V) (e.g., the absolute values of the negative and positive voltage levels are the same). To reduce power consumption, negative voltage level shifters have been developed that include low-voltage transistors (e.g., transistors rated for 1.8V-operation, for 1.5V-operation, or for 0.8V-operation). However, within such negative voltage level shifters, some of the low-voltage transistors operate outside their safe operating area (SOA) specifications.

For example, for metal oxide semiconductor field effect transistors (MOSFETs), SOA specifications can include maximum operating voltage limits, such as the maximum drain-source voltage (VDS), the maximum gate-source voltage (VGS), and the maximum operating gate-drain voltage (VGD). When only low-voltage MOSFETs are used in a conventional negative voltage level shifter, violations of one or more of these maximum operating voltage limitations occur in one or more of the MOSFETs. Design modifications intended to avoid such violations have included, for example, the use of at least some high-asymmetric MOSFETs (e.g., laterally diffused metal oxide semiconductor field effect transistors (LDMOSFETs)) in place of at-risk low-voltage MOSFETs and/or the use of external biasing. Unfortunately, these design modifications add to circuit complexity, power consumption, and area.

In view of the foregoing, disclosed herein are embodiments of a negative voltage level shifter structure (hereinafter referred to as the structure), which includes only stress-free, low-voltage transistors. The structure can include: a positive supply voltage node, which is connected to receive a positive supply voltage at a positive voltage level (+V) (e.g., 1.8 volts (V)); a negative supply voltage node, which is connected to receive a negative supply voltage at a negative voltage level (−V) (e.g., with the same absolute value as +V, such as −1.8V); and a ground node at 0.0V. The structure can further include two symmetric branches, each with multiple low-voltage pull-up transistors (e.g., P-type field effect transistors (PFETs)) and low-voltage pull-down transistors (e.g., N-type field effect transistors (NFETs)). For example, each branch can include: a stack of two pull-up transistors and two pull-down transistors, which are series-connected between the positive supply voltage node and the negative supply voltage node; an output node between the two pull-up transistors and the two pull-down transistors in the stack; and an input node connected to a control terminal of a top pull-up transistor in the stack. The input node on one branch can be connected to receive an input signal (IN) that switches between +V and 0.0V, whereas the input node on the other branch can be connected to receive an inverted input signal (INB) that switches between 0.0V and +V. The output node in one branch can output an output signal (OUT) that switches between +V and −V, whereas the output node in the other branch can output an inverted output signal (OUTB) that switches between −V and +V. Each branch can further an additional pull-down transistor, which is connected between the ground node and an intermediate node between the two pull-down transistors in the stack and which has a control terminal connected to the output node. These output-connected additional pull-down transistors are included in the structure to prevent voltage swings on the intermediate node that would otherwise result in SOA specification violations. Thus, all transistors within the disclosed structure remain stress-free and exhibit minimal off-state leakage. The disclosed structure is less complex and consumes less chip area than conventional negative voltage level shifter structures because it does not require any asymmetric high-voltage transistors or the use of external bias voltages to avoid device stress. Finally, an additional advantage of the disclosed structure that the generation of intermediate signals (also referred to herein as intermediate output signals) including an intermediate output signal (OUTM1), which swings between −V and 0.0V, and an inverted intermediate output signal (OUTM1B), which swings between 0.0V and −V.

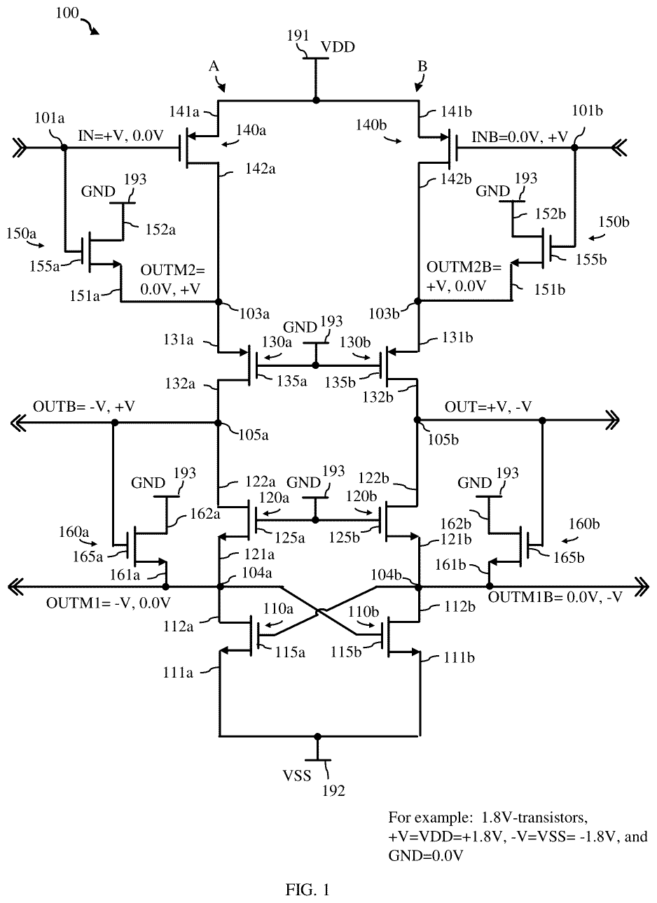

More particularly, FIG. 1 is a schematic diagram illustrating a disclosed embodiment of a negative voltage level shifter structure 100 (hereinafter referred to as structure 100). Structure 100 can include multiple transistors. As discussed in greater detail below, these transistors can include both pull-up transistors and pull-down transistors. For purposes of this disclosure, a pull-up transistor refers to a transistor configured to pull-up the voltage level on a node when in an on-state, whereas a pull-down transistor refers to a transistor configured to pull-down the voltage level on a node when in an on-state.

For purposes of illustration, the pull-up transistors and pull-down transistors of structure 100 are described below and illustrated in the figures as being metal oxide semiconductor field effect transistors (MOSFETs) and, particularly, P-type field effect transistors (PFETs) and N-type field effect transistors (NFETs), respectively. A MOSFET refers to a transistor that includes at least: a channel region in a semiconductor layer between a source region and a drain region; and a gate adjacent to the channel region. In a PFET, the source/drain regions can include semiconductor material doped so as to have P-type conductivity at a relatively high conductivity level (e.g., so as to be P+ source/drain regions). The channel region can be either doped so as to have N-type conductivity at a relatively low conductivity level (e.g., so as to be an N− channel region) or undoped (e.g., so as to be an intrinsic channel region). In an NFET, the source/drain regions can include semiconductor material doped so as to have N-type conductivity at a relatively high conductivity level (e.g., so as to be N+ source/drain regions). The channel region can be either doped so as to have P-type conductivity at a relatively low conductivity level (e.g., so as to be a P− channel region) or undoped (e.g., so as to be an intrinsic channel region). Examples of dopants that can be employed to achieve P-type or N-type conductivity are discussed in greater detail below. In any case, the gate can include a gate dielectric-gate conductor stack adjacent to the channel region. Various different configurations for PFETs and NFETs are well known in the art and, thus, the details thereof have been omitted from this specification in order to allow the reader to focus on the salient aspects of the disclosed embodiments (e.g., related to the unique voltage level shifter circuit structure).

FIG. 1 and the discussion thereof is, however, not intended to be limiting. For example, in alternative embodiments of structure 100, different types of pull-up and pull-down transistors other than PFETs and NFETs can be employed. For example, the pull-up transistors could be PNP-type bipolar junction transistors (BJTs) or heterojunction bipolar transistors (HBTs) and the pull-down transistors could be NPN-type BJTs or HBTs.

In any case, the transistors within structure 100 can all be low-voltage transistors. Specifically, they can all have the same relatively low maximum voltage rating as specified by the transistor data sheet. For example, the transistors can have a maximum voltage rating of 2.0 volts (V) or lower. Optionally, to minimize manufacturing complexity, the transistors can all be symmetric transistors. In some embodiments, the transistors can be PFETs or NFETs with a maximum voltage rating of 1.8V, of 1.5V or of 0.8V and the PFETs and NFETs can be symmetric MOSFETs. That is, they can be designed so that the source region and the drain region are the same (e.g., same size, doping, etc.) except for minor process variations and so that the same maximum voltage rating applies to the gate-source voltage (VGS), the gate-drain voltage (VGD), and the drain-source voltage (VDS). As discussed in greater detail below, structure 100 can further be configured to achieve negative voltage level shifting of an input signal (IN), which swings between a relatively low positive voltage level (+V) (e.g., of 2.0V or less, such as 1.8V, 1.5V or 0.8V) and 0.0V, to an output signal (OUT), which swings between +V and a negative voltage level (−V) with, for example, the same absolute value as +V and to do so without violating of the maximum voltage rating or requiring any external biasing.

Specifically, structure 100 can include a positive supply voltage node 191, a negative supply voltage node 192, and a ground node 193. Positive supply voltage node 191 can be electrically connected (e.g., to a positive supply voltage rail) to receive a positive supply voltage (VDD). When the positive voltage rail is powered on, VDD can be at a positive voltage level (+V). Negative supply voltage node 192 can be electrically connected (e.g., to a negative supply voltage rail) to receive a negative supply voltage (VSS). When the negative supply voltage rail is powered on, VSS can be at a negative voltage level (−V). −V can, for example, have the same absolute value as +V. For example, if +V=+1.8V, then −V=−1.8V. If +V=+1.5V, then −V=−1.5V. If +V=+0.8V, then −V=−0.8V. Thus, for example, if the maximum voltage rating of the transistors is 1.8V (i.e., if the transistors in structure 100 are 1.8V-transistors), then +V can be set at +1.8V and −V can be set at −1.8V. Alternatively, if the maximum voltage rating of the transistors is 1.5V (i.e., if the transistors in structure 100 are 1.5V-transistors), then +V can be set at +1.5V and −V can be set at −1.5V. Alternatively, if the maximum voltage rating of the transistors is 0.8V (i.e., if the transistors in structure 100 are 0.8V-transistors), then +V can be set at +0.8V and −V can be set at −0.8V. Ground node 193 can be connected to a ground rail (e.g., ground node 193 can be held constant at 0.0V).

As discussed in greater detail below, structure 100 can be connected to receive and output various signals (also referred to herein as voltage pulses). For purposes of this disclosure, a voltage pulse refers to an essentially rectangular direct current voltage signal that transitions (i.e., swings, switches, etc.) between a low voltage level and a high voltage level at regular and repeated intervals such that the voltage pulse is at a low voltage level for a first time period (t1), switches to a higher voltage level and remains at the high voltage level for a second time period (t2) (which is the same as or different from t1), switches back to the low voltage level and again remains at the low voltage level for t1, and so on.

Structure 100 can include a pair of input nodes 101a and 101b. Structure 100 can be connected to receive an input signal (IN) and an inverted input signal (INB) at input nodes 101a and 101b, respectively. IN can transition between +V and 0.0V. INB can be inverted with respect to IN. That is, INB can be at 0.0V when IN is at +V and can switch to +V when IN switches to 0.0V. Structure 100 can further include: pair of intermediate nodes 104a and 104b; a pair of additional intermediate nodes 103a and 103b; and a pair of output nodes 105a and 105b.

Structure 100 can include symmetric branches and, particularly, a first branch A and second branch B. First and second branches A and B can include parallel stacks of transistors connected between positive supply voltage node 191 and negative supply voltage node 192. Specifically, first branch A and second branch B can each include: a first pull-up transistor 140a, 140b; a second pull-up transistor 130a, 130b; a first pull-down transistor 120a, 120b; and a second pull-down transistor 110a, 110b, which are electrically connected in series between positive supply voltage node 191 and negative supply voltage node 192. First pull-up transistors 140a, 140b of first and second branches A and B (i.e., the top pull-up transistors in the stacks) can have control terminals 145a, 145b, which are electrically connected to input nodes 101a, 101b, respectively, for receiving IN and INB, respectively.

First branch A and second branch B can each include intermediate node 104a, 104b at the junction between first pull-down transistor 120a, 120b and second pull-down transistor 110a, 110b. First branch A and second branch B can each include additional intermediate node 103a, 103b at the junction between first pull-up transistor 140a, 140b and second pull-up transistor 130a, 130b. First branch A and second branch B can each further include output node 105a, 105b at the junction between (i.e., at the interconnect connecting) second pull-up transistor 130a, 130b and first pull-down transistor 120a, 120b.

Second pull-down transistors 110a and 110b of first and second branches A and B can be cross coupled. That is, a control terminal 115a of second pull-down transistor 110a in first branch A can be electrically connected to intermediate node 104b of second branch B and a control terminal 115b of second pull-down transistor 110b in second branch B can be electrically connected to intermediate node 104a of first branch A. Additionally, second pull-up transistors 130a and 130b in first and second branches A and B can have control terminals 135a and 135b, respectively, connected to ground node 193. Similarly, first pull-down transistors 120a and 120b in first and second branches A and B can have control terminals 125a and 125b, respectively, connected to ground node 193.

First and second branches A and B can each further include a third pull-down transistor 160a, 160b. Within each branch A and B, third pull-down transistor 160a, 160b can be electrically connected between ground node 193 and intermediate node 104a, 104b therein. Furthermore, within each branch A and B, third pull-down transistor 160a, 160b can have a control terminal 165a, 165b that is electrically connected to output node 105a, 105b therein. That is, third pull-down transistors 160a and 160b in first and second branches A and B can be controlled by output signals on output nodes 105a and 105b, respectively, as discussed in greater detail below. First and second branches A and B can each further include a fourth pull-down transistor 150a, 150b electrically connected between ground node 193 and additional intermediate node 103a, 103b. Furthermore, the fourth pull-down transistor 150a, 150b in a given branch A, B can have a control terminal 155a, 155b connected to the input node 101a, 101b for that given branch A, B. Thus, both the first pull-up transistor and the fourth pull-down transistor in each branch is input-controlled.

As mentioned above in some embodiments, the transistors of structure 100 can be MOSFETs. Thus, structure 100 is described in greater detail below as including PFET-type pull-up transistors and NFET-type pull-down transistors. Specifically, first branch A and second branch B can each include: a first PFET 140a, 140b; a second PFET 130a, 130b; a first NFET 120a, 120b; and a second NFET 110a, 110b, which are electrically connected in series between positive supply voltage node 191 and negative supply voltage node 192. Specifically, first PFET 140a, 140b can include: a source region 141a, 141b, which is electrically connected to positive supply voltage node 191; a drain region 142a, 142b, which is electrically connected to an additional intermediate node 103 a, 103b; a channel region between the source region 141 a, 141 b and the drain region 142a, 142b; and a gate 145a, 145b (i.e., a control terminal) adjacent to the channel region. Gate 145a of first PFET 140a in first branch A is connected to input node 101a for receiving IN, whereas gate 145b of first PFET 140b in second branch B is connected to input node 101b for receiving INB.

Second PFET 130a, 130b can include: a source region 131a, 131b, which is electrically connected to drain region 142 a, 142 b at additional intermediate node 103 a, 103b; a drain region 132a, 132b, which is electrically connected to output node 105a, 105b; a channel region between the source region 131a, 131b and the drain region 132a, 132b; and a gate 135a, 135b (i.e., a control terminal) adjacent to the channel region. Gate 135a of second PFET 130a in first branch A and gate 135b of second PFET 130b in second branch B can both be electrically connected to ground node 193.

First NFET 120a, 120b can include: a drain region 122a, 122b, which is electrically connected to drain region 132a, 132b of second PFET 130a, 130b at output node 105a, 105b; a source region 121a, 121b, which is electrically connected to an intermediate node 104a, 104b; a channel region between the source region 121a, 121b and the drain region 122a, 122b; and a gate 125a, 125b (i.e., a control terminal) adjacent to the channel region. Gate 125a of first NFET 120a in first branch A and gate 125b of first NFET 120b in second branch B can both be electrically connected to ground node 193.

Second NFET 110a, 110b can include: a drain region 112a, 112b, which is electrically connected to source region 121a, 121b of first NFET 120a, 120b at intermediate node 104a, 104b; a source region 111a, 111b, which is electrically connected to negative supply voltage node 192; a channel region between the source region 111a, 111b and the drain region 112a, 112b; and a gate 115a, 115b (i.e., a control terminal) adjacent to the channel region. Second NFET 110a in first branch A and second NFET 110b in second branch B can be cross coupled. That is, gate 115a of second NFET 110a in first branch A can be electrically connected to intermediate node 104b in second branch B and gate 115b of second NFET 110b in second branch B can be electrically connected to intermediate node 104a in first branch A.

First and second branches A and B can each also include a third NFET 160a, 160b. Third NFET 160a, 160b can include source region 161a, 161b, which is electrically connected to intermediate node 104a, 104b; a drain region 162a, 162b, which is electrically connected to ground node 193; a channel region between the source region 161a, 161b and the drain region 162a, 162b; and a gate 165a, 165b (i.e., a control terminal) adjacent to the channel region. Gate 165a of third NFET 160a in first branch A can be electrically connected to output node 105a, whereas gate 165b of third NFET 160b in second branch B can be electrically connected to output node 105b. That is, third NFETs 160a, 160b are output-controlled.

First and second branches A and B can each further include a fourth NFET 150a, 150b. Fourth NFET 150a, 150b can include source region 151a, 151b, which is electrically connected additional intermediate node 103a, 103b; a drain region 152a, 152b, which is electrically connected to ground node 193; a channel region between the source region 151a, 151b and the drain region 152a, 152b; and a gate 155a, 155b (i.e., a control terminal) adjacent to the channel region. Gate 155a of fourth NFET 150a in first branch A can be electrically connected to input node 101a, whereas gate 155b of fourth NFET 150b in second branch B can be electrically connected to input node 101b. That is, fourth NFETs 150a, 150b are, like first PFETs 140a, 140b, input-controlled.

Configured as described above and in response to IN (which transitions between +V and 0.0V) at input node 101a and INB (which concurrently transitions between 0.0V and +V) at input node 101b, structure 100 can generate and output various different signals at intermediate nodes 104a, 104b, at additional intermediate nodes 103a, 103b, and at output nodes 105 a, 105 b. Specifically, in response to IN (which transitions between +V and 0.0V) at input node 101 a and INB (which concurrently transitions between 0.0V and +V) at input node 101b, structure 100 can generate and output an intermediate signal (OUTM1, also referred to herein as an intermediate output signal) that swings between −V and 0.0V at intermediate node 104a within first branch A and an inverted intermediate signal (OUTM1B, also referred to herein as an inverted intermediate output signal) that concurrently swings between 0.0V and −V at intermediate output node 104b within second branch B. Additionally, in response to IN (which swings between +V and 0.0V) at input node 101a and INB (which concurrently swings between 0.0V and +V) at input node 101b, structure 100 can generate and output an additional intermediate signal (OUTM2, also referred to herein as an additional intermediate output signal) that swings between 0.0V and +V at additional intermediate node 103a within first branch A and an inverted additional intermediate signal (OUTM2B, also referred to herein as an additional intermediate output signal) that concurrently swings between +V and 0.0V at additional intermediate output node 103b within second branch B. Finally, in response to IN (which swings between +V and 0.0V) at input node 101a and INB (which concurrently swings between +V and 0.0V) at input node 101 b, structure 100 can generate and output an output signal (OUT, also referred to herein as a final output signal) that swings between +V and −V at output node 105b within second branch B and an inverted output signal (OUTB, also referred to herein as an inverted final output signal) that concurrently swings between −V and +V at output node 105a within first branch A.

Consider operation of structure 100 of FIG. 1, as described above, where all transistors are 1.8V MOSFETs, +V is 1.8V, and −V is −1.8V, particularly when IN is at +1.8V so INB is at 0.0V.

Within second branch B, due to INB being at 0.0V, first PFET 140b is on and fourth NFET 150b is off. As a result, OUTM2B on additional intermediate node 103b is pulled up to +1.8V. When OUTM2B is at +1.8V, second PFET 130b is on because its gate 135b is electrically connected to ground node 193 at 0.0V. As a result, OUT at output node 105b is also pulled up to +1.8V. With OUT at output node 105b at +1.8V, first NFET 120b is off and third NFET 160b is on. Thus, OUTM1B at intermediate node 104b is at 0.0V.

As mentioned above, second NFETs 110a and 110b in the first and second branches A and B are cross coupled. Specifically, intermediate node 104b of second branch B is electrically connected to gate 115a of second NFET 110a in first branch A and intermediate node 104a of first branch A is electrically connected to gate 115b of second NFET 110b in second branch B. Thus, OUTM1B on intermediate node 104b is applied to gate 115a of second NFET 110a in first branch A. Since OUTM1B on gate 115a is at 0.0V and source region 111a of that second NFET 110a is electrically connected to negative supply voltage node 192 at −1.8V, second NFET 110a in first branch A is on and pulls down OUTM1 on intermediate node 104a to −1.8V. Since OUTM1 on gate 115b is at −1.8V and source region 111b is also at −1.8V, second NFET 110b in second branch B will be off.

Additionally, within first branch A, source region 121a of first NFET 120a is electrically connected to intermediate node 104a (which is at −1.8V) and gate 125a of first NFET 120a is at 0.0V. Thus, first NFET 120a is on and pulls down OUTB on output node 105a to −V. Furthermore, since IN (which is at +1.8V) is applied to gate 145a of first PFET 140a and to gate 155a of fourth NFET 150a, first PFET 140a is off and fourth NFET 150a is on. Thus, OUTM2 on additional intermediate node 103a is at 0.0V. Since source region 131a of second PFET 130a (which is electrically connected to additional intermediate node 103a) and gate 135a of second PFET 130a (which is electrically connected to ground node 193) are both at 0.0V, second PFET 130a is off. Thus, OUTB at output node 105a is maintained at −1.8V.

Consider operation of this same structure, where all transistors are 1.8V MOSFETs, +V is 1.8V, and −V is −1.8V, particularly when IN is at 0.0V so INB is at +1.8V.

Within first branch A, due to IN being at 0.0V, first PFET 140a is on and fourth NFET 150a is off. As a result, OUTM2 on additional intermediate node 103a is pulled up to +1.8V. When OUTM2 is at +1.8V, second PFET 130a is on because its gate 135a is electrically connected to ground node 193 at 0.0V. As a result, OUTB at output node 105a is also pulled up to +1.8V. With OUTB at output node 105a at +1.8V, first NFET 120a is off and third NFET 160a is on. Thus, OUTM1 at intermediate node 104 a is at 0.0V.

As mentioned above, second NFETs 110a and 110b in the first and second branches A and B are cross coupled. Specifically, intermediate node 104b of second branch B is electrically connected to gate 1105a of second NFET 110a in first branch A and intermediate node 104a of first branch A is electrically connected to gate 115b of second NFET 110b in second branch B. Thus, OUTM1 on intermediate node 104a is applied to gate 115b of second NFET 110b in second branch B. Since OUTM1 on gate 115b is at 0.0V and source region 111b of that second NFET 110b is electrically connected to negative supply voltage node 192 at −1.8V, second NFET 110b in second branch B is on and pulls down OUTM1B on intermediate node 104b to −1.8V. Since OUTM1B on gate 115a is at −1.8V and source region 111a is also at −1.8V, second NFET 110a in first branch A will be off.

Additionally, within second branch B, source region 121b of first NFET 120b is electrically connected to intermediate node 104b (which is at −1.8V) and gate 125b of first NFET 120b is at 0.0V. Thus, first NFET 120b is on and pulls down OUT on output node 105b to −V. Furthermore, since INB (which is at +1.8V) is applied to gate 145b of first PFET 140b and to gate 155b of fourth NFET 150b, first PFET 140b is off and fourth NFET 150b is on. Thus, OUTM2B on additional intermediate node 103b is at 0.0V. Since source region 131b of second PFET 130b (which is electrically connected to additional intermediate node 103b) and gate 135b of second PFET 130b (which is electrically connected to ground node 193) are both at 0.0V, second PFET 130b is off. Thus, OUT at output node 105b is maintained at −1.8V.

As illustrated, during operation of structure 100, the maximum voltage differential between any two terminals (e.g., S-D, G-S, G-D) of any transistor is at or below the transistor voltage rating (e.g., of 1.8V). Thus, all transistors are stress free.

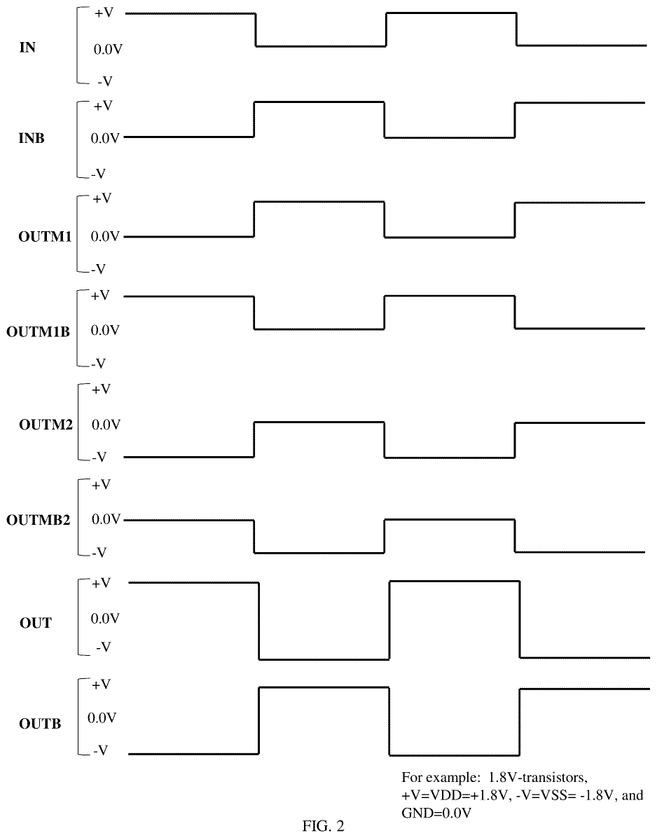

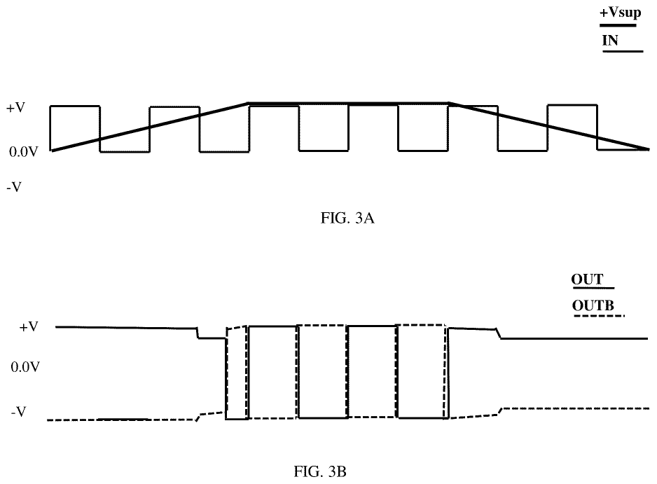

FIGS. 3A-3B are timing diagrams illustrating some of the voltage pulses of FIG. 2 during power-up and power down of the structure of FIG. 1 and, particularly, of the positive supply voltage node 191 therein. Specifically, FIG. 3A illustrates IN (which switches between 0.0V and +V (e.g., +1.8V)) during power-up and power-down of positive supply voltage node 191 from 0.0V to +V. FIG. 3B illustrates concurrent toggling of OUT and OUTB during power-up and power-down of positive supply voltage node 191. As illustrated in FIG. 3B, toggling of OUT and of OUTB begins when the positive voltage level on the positive supply voltage node 191 is approximately equal to V+ and ends when the positive voltage level drops below +V. Thus, structure 100 is operable without requiring, for example, any node pre-charge operations at power-up. That is, OUT and OUTB do not get stuck at intermediate node voltages and their nature does not change (i.e., they remain in phase with the input signal and are not interchanged/disturbed by the voltage ramp).

It should be understood that the terminology used herein is for the purpose of describing the disclosed structures and methods and is not intended to be limiting. For example, as used herein, the singular forms “a,” “an” and “the” are intended to include the plural forms as well, unless the context clearly indicates otherwise. Additionally, as used herein, the terms “comprises,” “comprising,” “includes” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A voltage level shifter comprising:
a ground node;
a negative supply voltage node; and
two branches, wherein each branch includes:
a first pull-down transistor connected between an output node and an intermediate node;
a second pull-down transistor connected between the intermediate node and the negative supply voltage node; and
a third pull-down transistor connected between the ground node and the intermediate node, wherein the third pull-down transistor includes a control terminal connected to the output node.

2. The voltage level shifter of claim 1,
wherein the two branches include a first branch and a second branch, and
wherein the second pull-down transistor in the first branch and the second pull-down transistor in the second branch are cross coupled.

3. The voltage level shifter of claim 1,
wherein the two branches include a first branch and a second branch, and
wherein the first pull-down transistor in the first branch and the first pull-down transistor in the second branch have control terminals connected to the ground node.

4. The voltage level shifter of claim 1, further comprising: a positive supply voltage node, wherein each branch further includes:
a first pull-up transistor connected between the positive supply voltage node and an additional intermediate node;
a second pull-up transistor connected between the additional intermediate node and the output node; and
a fourth pull-down transistor connected between the ground node and the additional intermediate node, wherein the first pull-up transistor and the fourth pull-down transistor include control terminals connected to an input node.

5. The voltage level shifter of claim 4, wherein the first pull-up transistor, the second pull-up transistor, the first pull-down transistor, the second pull-down transistor, the third pull-down transistor, and the fourth pull-down transistor are symmetric transistors with a same voltage-rating.

6. The voltage level shifter of claim 4,
wherein the two branches include a first branch and a second branch, and
wherein the second pull-up transistor in the first branch and the second pull-up transistor in the second branch have control terminals connected to the ground node.

7. The voltage level shifter of claim 4,
wherein the two branches include a first branch and a second branch,
wherein the input node in the first branch is connected to receive an input signal that swings between a positive voltage level and 0.0 volts (V), and
wherein the input node in the second branch is connected to receive an inverted input signal.

8. The voltage level shifter of claim 7,
wherein the positive supply voltage node is connected to receive a positive supply voltage at the positive voltage level,
wherein the negative supply voltage node is connected to receive a negative supply voltage at a negative voltage level, and
wherein the ground node is at 0.0 volts.

9. The voltage level shifter of claim 8, wherein the positive voltage level and the negative voltage level have a same absolute value.

10. The voltage level shifter of claim 8,
wherein the intermediate node in the first branch outputs an intermediate signal that swings between the negative voltage level and 0.0V and the intermediate node in the second branch outputs an inverted intermediate signal, and
wherein the output node in the second branch outputs an output signal that swings between the positive voltage level and the negative voltage level and the output node in the first branch outputs an inverted output signal.

11. A voltage level shifter comprising:
a ground node;
a negative supply voltage node; and
two branches, wherein each branch includes:
a first N-type field effect transistor (NFET) connected between an output node and an intermediate node;
a second NFET connected between the intermediate node and the negative supply voltage node; and
a third NFET connected between the ground node and the intermediate node, wherein the third NFET includes a gate connected to the output node.

12. The voltage level shifter of claim 11,
wherein the two branches include a first branch and a second branch, and
wherein the second NFET in the first branch and the second NFET in the second branch are cross coupled.

13. The voltage level shifter of claim 11,
wherein the two branches include a first branch and a second branch, and
wherein the first NFET in the first branch and the first NFET in the second branch have gates connected to the ground node.

14. The voltage level shifter of claim 11, further comprising: a positive supply voltage node, wherein each branch further includes:
a first P-type field effect transistor (PFET) connected between the positive supply voltage node and an additional intermediate node;
a second PFET connected between the additional intermediate node and the output node; and
a fourth NFET connected between the ground node and the additional intermediate node, wherein the first PFET and the fourth NFET include gates connected to an input node.

15. The voltage level shifter of claim 14, wherein the first PFET, the second PFET, the first NFET, the second NFET, the third NFET, and the fourth NFET are symmetric transistors with a same voltage-rating.

16. The voltage level shifter of claim 14,
wherein the two branches include a first branch and a second branch, and
wherein the second PFET in the first branch and the second PFET in the second branch have gates connected to the ground node.

17. The voltage level shifter of claim 14,
wherein the two branches include a first branch and a second branch,
wherein the input node in the first branch is connected to receive an input signal that swings between a positive voltage level and 0.0 volts (V), and
wherein the input node in the second branch is connected to receive an inverted input signal.

18. The voltage level shifter of claim 17,
wherein the positive supply voltage node is connected to receive a positive supply voltage at the positive voltage level,
wherein the negative supply voltage node is connected to receive a negative supply voltage at a negative voltage level, and
wherein the ground node is at 0.0 volts.

19. The voltage level shifter of claim 18,
wherein the positive voltage level and the negative voltage level have a same absolute value,
wherein the intermediate node in the first branch outputs an intermediate signal that swings between the negative voltage level and 0.0V and the intermediate node in the second branch outputs an inverted intermediate signal, and
wherein the output node in the second branch outputs an output signal that swings between the positive voltage level and the negative voltage level and the output node in the first branch outputs an inverted output signal.

20. A voltage level shifter comprising:
a positive supply voltage node;
a negative supply voltage node;
a ground node; and
two branches including a first branch and a second branch,
wherein the first branch and the second branch each include:
a first pull-up transistor, a second pull-up transistor, a first pull-down transistor, and a second pull-down transistor connected in series between the positive supply voltage node and the negative supply voltage node;
a third pull-down transistor connected between the ground node and an intermediate node between the first pull-down transistor and the second pull-down transistor, wherein the third pull-down transistor includes a control terminal connected to an output node between the second pull-up transistor and the first pull-down transistor; and
a fourth pull-down transistor connected between the ground node and an additional intermediate node between the first pull-up transistor and the second pull-up transistor, wherein the second pull-up transistor and the fourth pull-down transistor include control terminals connected to an input node,
wherein the second pull-down transistor in the first branch and the second pull-down transistor in the second branch are cross coupled, and
wherein the first pull-down transistor in the first branch, the first pull-down transistor in the second branch, the second pull-up transistor in the first branch, and the second pull-up transistor in the second branch have control terminals connected to the ground node.
